(19) United States
(12) Patent Application Publication
(10) Pub. No.: US 2011/0045260 A1
(43) Pub. Date: Feb. 24, 2011

(54) TRANSPARENT CONDUCTIVE LAMINATE FOR A SEMICONDUCTOR DEVICE AND METHOD OF IMPROVING COLOR HOMOGENEITY OF THE SAME

(76) Inventors: Kuang-Rong Lee, Tainan City (TW); Wun-Wei Hu, Tainan City (TW); Chun-Ping Chan, Kaohsiung City (TW)

Correspondence Address: VEDDER PRICE P.C., 222 N. LASALLE STREET, CHICAGO, IL, 60601, US

(21) Appl. No.: 12/758,107

(22) Filed: Apr. 12, 2010

(30) Foreign Application Priority Data
Aug. 18, 2009 (TW) 098127709

(51) Int. Cl. B32B 7/02; H01L 21/66

(52) U.S. Cl. 428/213; 428/212; 438/7; 257/E21.528

(57) ABSTRACT

A transparent conductive laminate for a semiconductor device includes a substrate, first and second refracting films, and a transparent conductive film formed on the second refracting film and having a pattern defined by etched and non-etched regions. The optical thicknesses of the first and second refracting films are controlled to reduce a difference between CIE b* color values produced in the etched and non-etched regions. The CIE b* color values are smaller than 1.15, and the differential value therebetween is less than 0.35 so that the pattern of the transparent conductive film can be obscured or hidden, thereby improving color homogeneity. A method of improving color homogeneity of the laminate is also disclosed.

### CROSS-REFERENCE TO RELATED APPLICATION

This application claims priority of Taiwanese application no. 098127709, filed on Aug. 18, 2009.

### BACKGROUND OF THE INVENTION

1. Field of the Invention

This invention relates to a transparent conductive laminate for a semiconductor device, such as a display device, and a method of improving color homogeneity of the transparent conductive laminate. More particularly, this invention relates to an upper transparent conductive laminate for a touch panel, and a method of improving color homogeneity of the transparent conductive laminate.

2. Description of the Related Art

A touch panel is a device provided on a display surface of various display apparatuses, such as a liquid crystal display and a cathode ray tube (CRT), and enables input of information by touching a screen of the touch panel. A resistive touch panel includes upper and lower transparent conductive laminates which are arranged so that transparent conductive films respectively provided on the two laminates are disposed to face each other with a predetermined gap therebetween. When a user touches an item on the screen, the transparent conductive films are brought into contact to produce a signal.

Because the conventional transparent conductive laminates of the touch panel of this type have a relatively low transmittance in shorter wavelength of the visible light, the transparent conductive laminates are transparent but with a yellowish tone.

In order to obtain upper and lower transparent conductive laminates with higher transmittances in all wavelength of the visible light, various methods have been proposed for decreasing b* color value in CIE L*a*b* color space of the transparent conductive laminates. Examples of the relevant literature include JP 2003-171147, JP 2007-299534, JP 2006-346878 (i.e., TW 2007-30933), JP 2004-184579, JP 2007-276322, JP 2008-49518, etc.

However, when the transparent conductive film in the transparent conductive laminate is etched to form patterns of circuits or electric capacitors in the touch panel, the etched regions of the transparent conductive film present a color different from that produced in the non-etched regions. As a result, the patterns of the transparent conductive films, especially the patterns of the upper transparent conductive film, are visible from the touch panel. Therefore, the conventional transparent conductive laminate still has a problem of poor color homogeneity due to the visible patterns therein, although the transmittance of the transparent conductive laminate in all wavelength of the visible light is improved by the prior art methods.

### SUMMARY OF THE INVENTION

Therefore, an object of the present invention is to provide a transparent conductive laminate for a semiconductor device, and a method of improving color homogeneity of the same that can overcome both problems of yellow-tone production and poor color homogeneity encountered by the prior art. In other words, by the present invention, the patterns of the transparent conductive film are not visible, and the display device using the transparent conductive laminate of the present invention can be provided with a more uniform color without yellow-tone.

According to one aspect of the present invention, there is provided a transparent conductive laminate for a semiconductor device, comprising:

a substrate having opposite first and second surfaces;

a first refracting film formed on the first surface of the substrate;

a second refracting film formed on the first refracting film and having a refractive index smaller than that of the first refracting film; and

a transparent conductive film formed on the second refracting film and having a pattern defined by etched regions and non-etched regions.

The first and second refracting films have optical thicknesses that are controlled so as to reduce a difference between colors produced in the etched and non-etched regions.

The etched and non-etched regions produce colors that satisfy the following relations:

b1*<1.15 (1)

b2*<1.15 (2)

Δb*=|b1*−b2*|<0.35 (3)

wherein b1* is a first CIE b* color value obtained by a measurement conducted on the transparent conductive laminate before the transparent conductive film is formed on the second refracting film and corresponds to a CIE b* color value produced in the etched regions;

wherein b2* is a second CIE b* color value obtained by a measurement conducted on the transparent conductive laminate after the transparent conductive film is formed but prior to forming the pattern and corresponds to a CIE b* color value produced in the non-etched regions.

According to another aspect of the present invention, there is provided a method of improving color homogeneity of a transparent conductive laminate for a semiconductor device, the transparent conductive laminate including a first refracting film formed on a substrate, a second refracting film formed on the first refracting film and having a refractive index smaller than that of the first refracting film, and a transparent conductive film formed on the second refracting film and having a pattern defined by etched regions and non-etched regions.

The method comprises: determining a first CIE b* color value (b1*) through a measurement conducted on the transparent conductive laminate before the transparent conductive film is formed on the second refracting film, wherein b1* corresponds to a CIE b* color value produced in the etched region; determining a second CIE b* color value (b2*) through a measurement conducted on the transparent conductive laminate after the transparent conductive film is formed but prior to forming the pattern, wherein b2* corresponds to a CIE b* color value produced in the non-etched region; determining a differential value (Δb*) between the first and second CIE b* color values (b1* and b2*); and controlling optical thicknesses of the first and second refracting films so as to reduce the differential value (Δb*), thereby obscuring or hiding the pattern of the transparent conductive film, and improving color homogeneity.

Preferably, the optical thicknesses of the first and second refracting films are controlled such that the first and second CIE b* color values (b1* and b2*) are less than 1.15 and the differential value (Δb*) is less than 0.35.

The CIE b* color values (b1* and b2*) in this specification refer to the b* color values in CIE L*a*b* color space. The larger the CIE b* color value, the closer will be the color of the transparent conductive laminate to yellow. For example, in the case of the transparent conductive laminate, when the CIE b* color value is between 4 and 2, the color of the transparent conductive laminate is yellow toned. When the CIE b* color value of the transparent conductive laminate is lower than 1.15, the transparent conductive laminate has no yellow-tone.

On the other hand, when the differential value (A b*) between the first and second CIE b* color values (b1* and b2*) is smaller than 0.35, the difference between the colors of the etched and non-etched regions can be reduced, and the pattern can be obscured or even hidden.

Furthermore, the optical thickness of the first or second refracting film in this specification refers to a product of a physical thickness of the refracting film and a refractive index of the refracting film.

### BRIEF DESCRIPTION OF THE DRAWINGS

Other features and advantages of the present invention will become apparent in the following detailed description of the preferred embodiments of the invention, with reference to the accompanying drawings, in which:

FIG. 1 is a cross-sectional view of a transparent conductive laminate for a semiconductor device according to the first embodiment of the present invention, wherein a modifying film is formed between a substrate and a first refracting layer thereof;

FIG. 2 is a graph showing the differential values (Δb*) of Examples 1˜3 and Comparative Examples 1˜4 in Experiment 1;

FIG. 3 is a graph showing the differential values (Δb*) of Examples 5˜6 and Comparative Examples 5˜6 in Experiment 2;

FIG. 4 is a cross-sectional view of a transparent conductive laminate for a semiconductor device according to the second embodiment of the present invention;

FIG. 5 is a cross-sectional view of a transparent conductive laminate for a semiconductor device according to the third embodiment of the present invention; and

FIG. 6 is a graph showing the differential values (Δb*) of Examples 7˜9 and Comparative Examples 7˜8 in Experiment 3.

### DETAILED DESCRIPTION OF THE PREFERRED EMBODIMENTS

Before the present invention is described in greater detail with reference to the accompanying preferred embodiments, it should be noted herein that like elements are denoted by the same reference numerals throughout the disclosure.

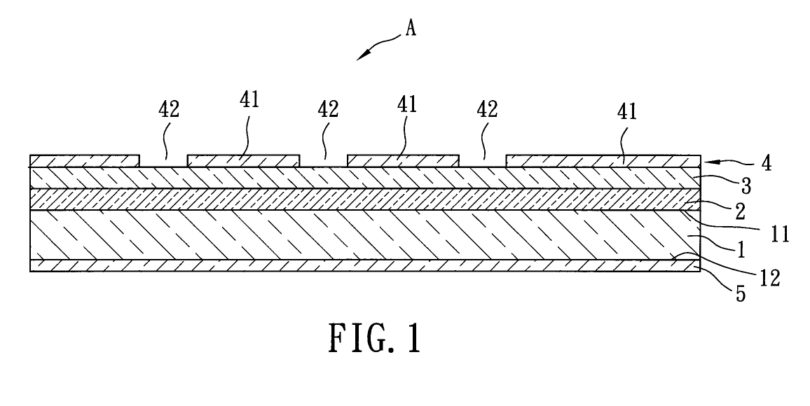

A method of improving color homogeneity of a transparent conductive laminate in this invention is different from the conventional method for improving transmittance of a transparent conductive laminate in order to overcome the problem of yellow tone. In this invention, by controlling optical thicknesses of two refracting films 2, 3 that are interposed between a substrate 1 and a transparent conductive film 4 as shown in FIG. 1, the transmittance of the transparent conductive laminate is improved, and the color homogeneity thereof is also improved.

Hereinafter, three embodiments of this invention are described in detail.

FIG. 1 illustrates a transparent conductive laminate (A) for a touch panel according to the first embodiment. The transparent conductive laminate (A) includes a substrate 1, a first refracting film 2, a second refracting film 3, a transparent conductive film 4, and a modifying film 5.

The substrate 1 has opposite first and second surfaces 11, 12, and can be made of polyethylene terephthalate (PET), polycarbonate (PC), polyethylene (PE), etc. The substrate 1 is preferably made of PET.

The first refracting film 2 is formed on the first surface 11 of the substrate 1, and can be made of TiO₂, Nb₂O₅, NbO, CeO, indium tin oxide (ITO), etc. Preferably, the first refracting film 2 is made of Nb₂O₅ and has an optical thickness ranging from 11 nm to 16 nm. More preferably, the optical thickness of the first refracting film 2 ranges from 12 nm to 15 nm.

The second refracting film 3 is formed on the first refracting film 2, has a refractive index smaller than that of the first refracting film 2, and can be made of SiO₂, Si₃N₄, MgF₂, etc. Preferably, the second refracting film 3 is made of SiO₂, and has an optical thickness ranging from 60 nm to 90 nm. More preferably, the optical thickness of the second refracting film 3 ranges from 60 nm to 80 nm.

The transparent conductive film 4 is formed on the second refracting film 3 and is preferably made of indium tin oxide (ITO). The transparent conductive film 4 as shown in FIG. 1 is etched to have a pattern defined by a plurality of non-etched regions 41 and a plurality of etched regions 42. The positions of the non-etched regions 41 of the transparent conductive film 4 are determined by the design of the circuits or electric capacitors of the transparent conductive laminate (A) of the touch panel.

The modifying film 5 is formed on the second surface 12 of the substrate 1, and can be a hard coat film made of a reactive hardening resin containing functional particles, a film capable of reducing reflectance and improving transmittance, or a functional film capable of diffusing light uniformly. The modifying film 5 can be any kind of film that satisfies the requirements of the semiconductor device. In this embodiment, the modifying film 5 is the hard coat film. Through the protection by the hard coat film, the touch panel can be protected from scraping.

The transmittance of the transparent conductive laminate (A) in all wavelength of visible light is improved by the provision of the second refracting film 3 that has a refractive index smaller than that of the first refracting film 2. The patterns (the non-etched regions 41) in the transparent conductive laminate (A) are obscured by controlling the optical thicknesses of the first and second refracting films 2, 3.

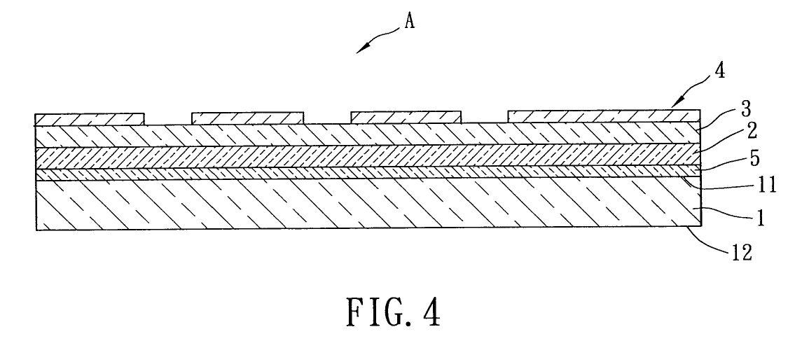

FIG. 4 illustrates a transparent conductive laminate (A) for a touch panel according to the second embodiment. The second embodiment differs from the first embodiment only in that the modifying film 5 is formed between the first surface 11 of the substrate 1 and the first refracting film 2.

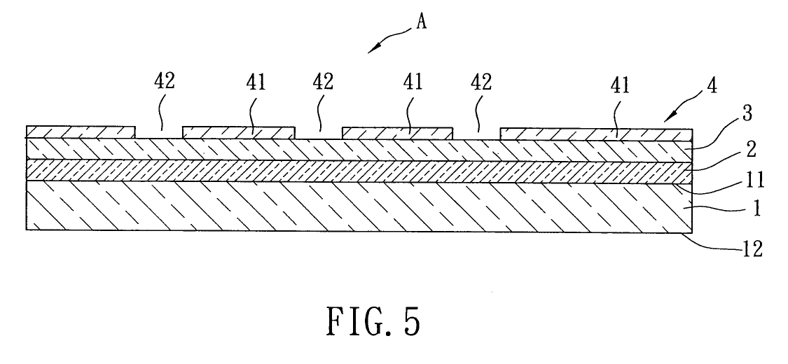

FIG. 5 illustrates a transparent conductive laminate (A) for a touch panel according to the third embodiment. The third embodiment differs from the second embodiment only in that the modifying film 5 is not provided, and that the optical thickness of the first refracting film 2 is different.

In this embodiment, the controlled optical thickness of the first refracting film 2 is preferably ranging from 20 nm to 29 nm, and is more preferably ranging from 22 nm to 28 nm.

According to the method of the present invention, color homogeneity of the transparent conductive laminate (A) is improved by controlling the optical thicknesses of the first and second refracting films 2 and 3 which can affect the CIE b* color values produced in the non-etched and etched regions 41 and 42. The CIE b* color value of the non-etched regions 41 is determined in terms of the first CIE b* color value (b1*) obtained by a measurement conducted on the transparent conductive laminate (A) before the transparent conductive film 4 is formed. The CIE b* color value of the etched regions 42 is determined in terms of the second CIE b* color value (b2*) obtained through a measurement conducted on the transparent conductive laminate (A) after the transparent conductive film 4 is formed but prior to forming the pattern. By controlling the optical thicknesses of the first and second refracting films 2 and 3, the differential value (Δb*) between (b1*) and (b2*) (i.e., Δb*=|b1*−b2*|) can be reduced. As a result, the difference between the colors of the non-etched and etched regions 41 and 42 can be decreased and hence the pattern of the transparent conductive film 4 can be obscured or hidden, thereby improving color homogeneity.

### EXPERIMENTS

### Investigation of b1*, b2* and (Δb*) for Different Optical Thicknesses

### Experiment 1

In Experiment 1, a commercial product of trade name: FE-RHPC56N including a substrate that incorporates a modifying film made of a reactive hardening resin is used to prepare Examples 1-4 and Comparative Examples 1-4 which have the structure shown in FIG. 1. The thickness of the substrate 1 is 125 μm, and the thickness of the modifying film 5 is about 5 μm.

The first refracting film 2 is made of Nb₂O₅. The second refracting film 3 is made of SiO₂. The transparent conductive film 4 is made of indium tin oxide (ITO), and has a resistance of 320 Ω/mm².

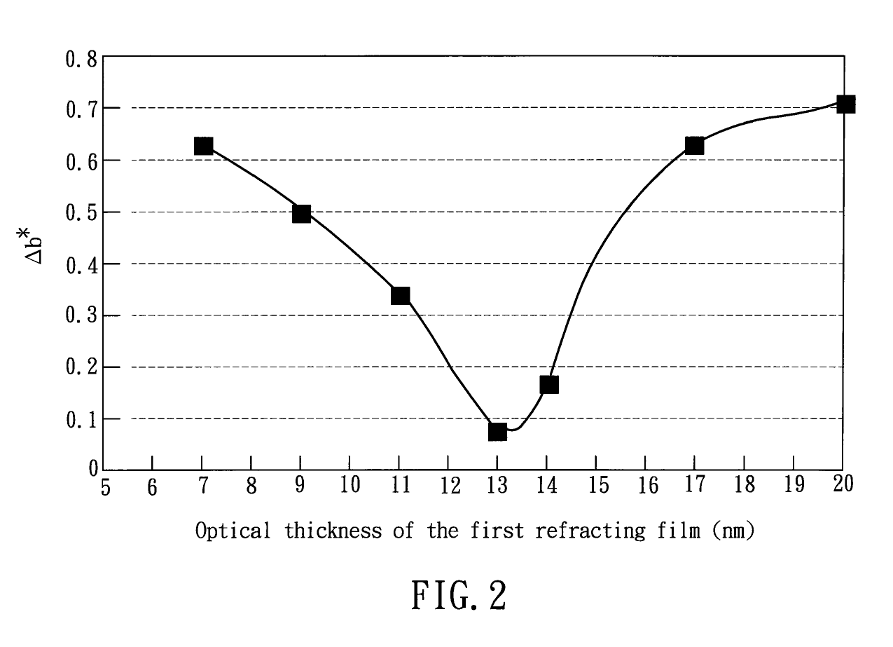

In this experiment, Examples 1-4 and Comparative Examples 1˜4 are provided with different optical thicknesses of the first and second refracting films as shown in Table 1. The transmittances, and the first and second CIE b* color values (b1* and b2*) are measured by using a spectrophotometer (Konica Minolta, model: CM-3600d) to determine the differential value (Δb*). The results are all shown in Table 1 and FIG. 2.

TABLE 1

| | | | Before the | | After the | | |
|---|---|---|---|---|---|---|---|
| | | | transparent | | transparent | | |
| | First | Second | conductive film is | | conductive film is | | |
| | refracting | refracting | formed | | formed | | |
| | layer | layer | Transmittance | | Transmittance | | |
| | (nm) | (nm) | (%) | B1* | (%) | b2* | Δb* |
| Ex. 1 | 14 | 80 | 88.2 | 0.82 | 88.02 | 0.65 | 0.17 |
| Ex. 2 | 13 | 80 | 88.5 | 0.80 | 87.90 | 0.72 | 0.08 |
| Ex. 3 | 11 | 80 | 88.5 | 0.80 | 88.07 | 1.14 | 0.34 |
| Ex. 4 | 13 | 90 | 88.7 | 0.80 | 88.05 | 0.75 | 0.05 |
| Comp. Ex. 1 | 20 | 80 | 86.7 | 0.89 | 88.16 | 0.18 | 0.71 |
| Comp. Ex. 2 | 17 | 80 | 87.4 | 0.88 | 88.01 | 0.25 | 0.63 |
| Comp. Ex. 3 | 9 | 80 | 88.9 | 0.78 | 88.21 | 1.28 | 0.50 |
| Comp. Ex. 4 | 7 | 80 | 89.1 | 0.78 | 88.30 | 1.41 | 0.63 |

As shown in Table 1, the transparent conductive laminates of Comparative Examples 3 and 4, the second CIE b* color values (b2*) of which are both larger than 1.15, are transparent but with a yellowish tone. Furthermore, the optical thickness of the first refracting film is larger than 16 nm in Comparative Examples 1 and 2 and is smaller than 11 nm in Comparative Examples 3 and 4. The differential values (Δb*) of Comparative Examples 1 to 4 are all larger than 0.35, and thus, the patterns in the transparent conductive laminates of Comparative Examples 1 to 4 can be observed clearly. Therefore, all of Comparative Examples 1˜4 have the problems of yellow-tone and poor color homogeneity.

On the contrary, in Examples 1˜4, the CIE b* color values (b1* and b2*) are all smaller than 1.15, and the differential values (Δb*) are all smaller than 0.35. Therefore, all of Examples 1˜4 can overcome both of the problems of yellow-tone and poor color homogeneity.

### Experiment 2

Examples 5 and 6 and Comparative Examples 5 and 6 in this experiment have the same structure and the same materials as Examples 1-4 except that a commercial product of KIMOTO Co. Ltd. (trade name: KIMOTO-GSAB) is used in place of the commercial product (FE-RHPC56N). The transparent conductive film 4 has a resistance of 312 Ω/mm².

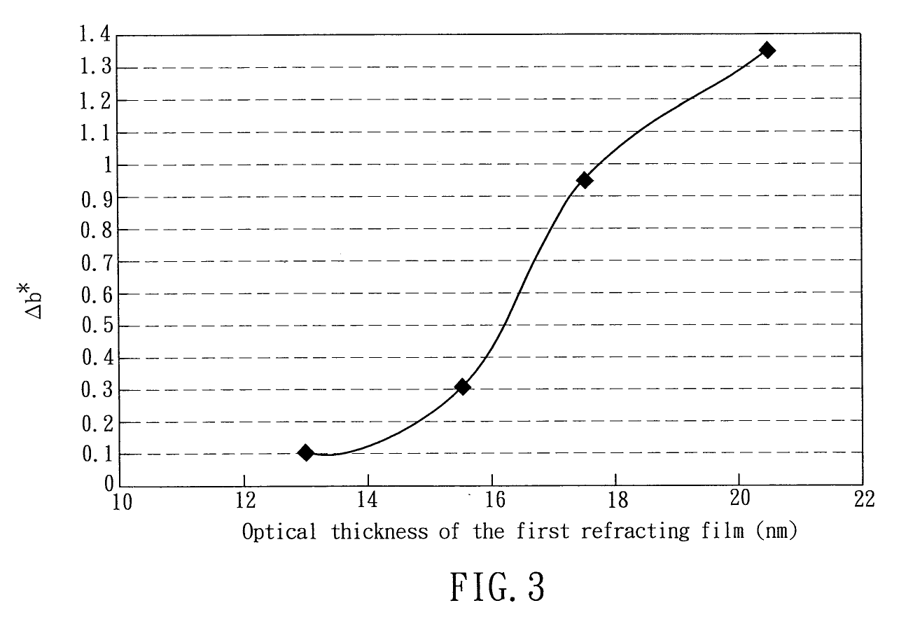

This experiment is conducted to measure the same items as those in Experiment 1. The results are all shown in Table 2 and FIG. 3.

TABLE 2

| | | | Before the | | After the | | |
|---|---|---|---|---|---|---|---|
| | | | transparent | | transparent | | |
| | First | Second | conductive film is | | conductive film is | | |
| | refracting | refracting | formed | | formed | | |
| | layer | layer | Transmittance | | Transmittance | | |
| | (nm) | (nm) | (%) | b1* | (%) | b2* | Δb* |
| Ex. 5 | 13.0 | 80 | 89.22 | 0.8 | 88.22 | 0.91 | 0.11 |
| Ex. 6 | 15.5 | 80 | 88.51 | 0.85 | 88.41 | 0.54 | 0.31 |
| Comp. Ex. 5 | 17.5 | 80 | 87.72 | 0.97 | 88.53 | 0.02 | 0.95 |
| Comp. Ex. 6 | 20.5 | 90 | 87.13 | 0.98 | 88.78 | −0.37 | 1.35 |

As shown in Table 2, in Comparative Examples 5 and 6, the CIE b* color values (b1* and b2*) are all smaller than 1.15, but the differential values (Δb*) are all larger than 0.35. Thus, although the transparent conductive laminates of Comparative Examples 5 and 6 are not yellow-tone, those laminates still cannot overcome the problem of poor color homogeneity due to the visible patterns in the transparent conductive laminate.

On the contrary, in Examples 5 and 6, the CIE b* color values (b1* and b2*) are all smaller than 1.15, and the differential values (Δb*) are all smaller than 0.35. Therefore, Examples 5˜6 can overcome both of the problems of yellow-tone and poor color homogeneity.

From Experiments 1 and 2, it is observed that, when a transparent conductive laminate (A) includes the modifying film 5, the first refracting film 2 should be controlled to have an optical thickness ranging from 11 nm to 16 nm, preferably, from 12 nm to 15 nm. When the optical thickness is too large, the transparent conductive laminate (A) will encounter the problem of poor color homogeneity. When the optical thickness is too small, the transparent conductive laminate (A) will encounter the problem of yellow-tone and poor color homogeneity. It is also observed that the second refracting film 3 should be controlled to have an optical thickness ranging from 60 nm to 90 nm, preferably, from 60 nm to 80 nm. When the optical thickness of the second refracting film 3 is too large or too small, the problems of yellow-tone and poor color homogeneity cannot be overcome.

### Experiment 3

In Experiment 3, Examples 7-9 and Comparative Examples 7 and 8 having the structure shown in FIG. 5 are prepared using a commercial product of TOYOBO Co. Ltd. (trade name: TOYOBO A4150) as the substrate. The first and second refracting films 2 and 3 are made respectively from Nb₂O₅ and SiO₂. The transparent conductive film 4 has a resistance of 290 Ω/mm².

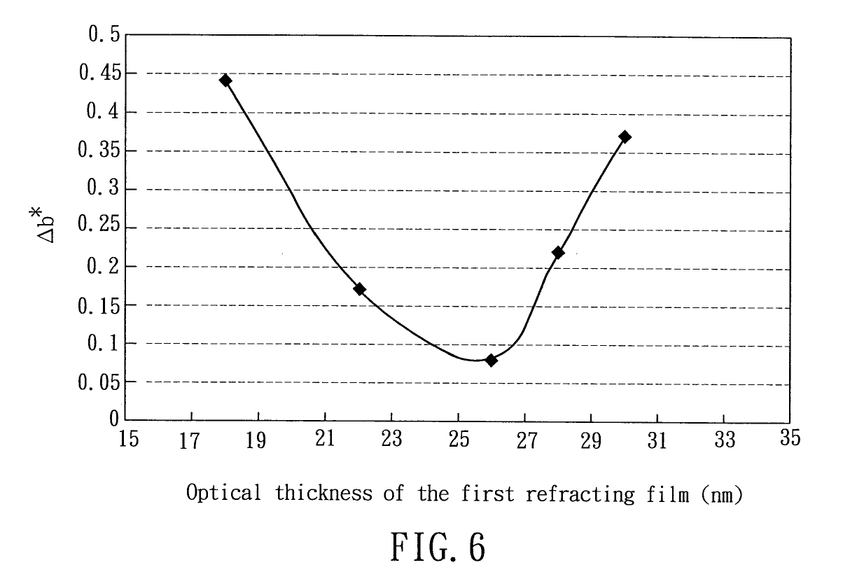

This experiment is conducted to measure the same items as those in Experiment 1. The results are all shown in Table 3 and FIG. 6.

TABLE 3

| | | | Before the | | After the | | |
|---|---|---|---|---|---|---|---|
| | | | transparent | | transparent | | |
| | First | Second | conductive film is | | conductive film is | | |
| | refracting | refracting | formed | | formed | | |
| | layer | layer | Transmittance | | Transmittance | | |
| | (nm) | (nm) | (%) | b1* | (%) | b2* | Δb* |
| Ex. 7 | 28 | 80 | 91.26 | 0.35 | 90.76 | 0.57 | 0.22 |
| Ex. 8 | 26 | 80 | 91.31 | 0.32 | 90.84 | 0.40 | 0.08 |
| Ex. 9 | 22 | 80 | 91.50 | 0.32 | 90.86 | 0.49 | 0.17 |
| Comp. Ex. 7 | 30 | 80 | 91.34 | 0.37 | 90.79 | 0 | 0.37 |
| Comp. Ex. 8 | 18 | 80 | 91.70 | 0.29 | 90.91 | 0.73 | 0.44 |

As shown in Table 3, in Comparative Examples 7 and 8, the CIE b* color values (b1* and b2*) are all smaller than 1.15, but the differential values (Δb*) are all larger than 0.35. Thus, although the transparent conductive laminates of Comparative Examples 7 and 8 have no yellow-tone, these laminates still suffer from the problem of poor color homogeneity due to the visible patterns therein.

On the contrary, in Examples 7˜9, the CIE b* color values (b1* and b2*) are all smaller than 1.15, and the differential values (Δb*) are all smaller than 0.35. Therefore, Examples 7˜9 can overcome both of the problems of yellow-tone and poor color homogeneity.

Based on Examples 7˜9 in Table 3, when the transparent conductive laminate (A) does not have the modifying film 5, the first refracting film 2 should be controlled to have an optical thickness ranging from 20 nm to 29 nm, and the second refracting film should be controlled to have an optical thickness ranging from 60 nm to 90 nm. Preferably, the first refracting film 2 has an optical thickness ranging from 22 nm to 28 nm, and the second refracting film has an optical thickness ranging from 60 nm to 80 nm.

By controlling the optical thicknesses of the first and second refracting films 2, 3, the first and second CIE b* color values (b1* and b2*) can be reduced to be less than 1.15, and the differential value (Δb*) can be reduced to be less than 0.35. Not only can the yellow-tone problem be resolved, but the color homogeneity of the transparent conductive laminate for a touch panel can be greatly improved as well.

While the present invention has been described in connection with what are considered the most practical and preferred embodiments, it is understood that this invention is not limited to the disclosed embodiments but is intended to cover various arrangements included within the spirit and scope of the broadest interpretations and equivalent arrangements.

What is claimed is:

1. A transparent conductive laminate for a semiconductor device, comprising:
a substrate having opposite first and second surfaces;
a first refracting film formed on said first surface of said substrate;
a second refracting film formed on said first refracting film and having a refractive index smaller than that of said first refracting film; and
a transparent conductive film formed on said second refracting film and having a pattern defined by etched regions and non-etched regions;
said first and second refracting films having optical thicknesses that are controlled so as to reduce a difference between colors produced in said etched and non-etched regions;
said etched and non-etched regions producing colors that satisfy the following relations:
b1*<1.15 (1)
b2*<1.15 (2)
Δb*=|b1*−b2*|<0.35 (3)
wherein b1* is a CIE b* color value obtained by a measurement conducted on said transparent conductive laminate before said transparent conductive film is formed and corresponds to a CIE b* color value produced in said etched regions;
wherein b2* is a CIE b* color value obtained by a measurement conducted on said transparent conductive laminate after said transparent conductive film is formed but prior to forming the pattern, and corresponds to a CIE b* color value produced in said non-etched regions.

2. The transparent conductive laminate of claim 1, wherein said transparent conductive film is made of indium tin oxide.

3. The transparent conductive laminate of claim 1, further comprising a modifying film formed on said second surface of said substrate.

4. The transparent conductive laminate of claim 3, wherein the optical thickness of said first refracting film ranges from 11 nm to 16 nm, and the optical thickness of said second refracting film ranges from 60 nm to 90 nm.

5. The transparent conductive laminate of claim 1, further comprising a modifying film formed between said first surface of said substrate and said first refracting film.

6. The transparent conductive laminate of claim 5, wherein the optical thickness of said first refracting film ranges from 12 nm to 15 nm.

7. The transparent conductive laminate of claim 6, wherein the optical thickness of said second refracting film ranges from 60 nm to 80 nm.

8. The transparent conductive laminate of claim 3, wherein said modifying film is a hard coated film made of a reactive hardening resin.

9. The transparent conductive laminate of claim 1, wherein the optical thickness of said first refracting film ranges from 20 nm to 29 nm, and the optical thickness of said second refracting film ranges from 60 nm to 90 nm.

10. The transparent conductive laminate of claim 9, wherein the optical thickness of said first refracting film ranges from 22 nm to 28 nm.

11. The transparent conductive laminate of claim 9, wherein the optical thickness of said second refracting film ranges from 60 nm to 80 nm.

12. A method of improving color homogeneity of a transparent conductive laminate for a semiconductor device, the transparent conductive laminate including a first refracting film formed on a substrate, a second refracting film formed on the first refracting film and having a refractive index smaller than that of the first refracting film, and a transparent conductive film formed on the second refracting film and having a pattern defined by etched regions and non-etched regions, the method comprising:
determining a first CIE b* color value (b1*) through a measurement conducted on the transparent conductive laminate before the transparent conductive film is formed on the second refracting film, wherein b1* corresponds to a CIE b* color value produced in the etched region;
determining a second CIE b* color value (b2*) through a measurement conducted on the transparent conductive laminate after the transparent conductive film is formed but prior to forming the pattern, wherein b2* corresponds to a CIE b* color value produced in the non-etched region;
determining a differential value (Δb*) between the first and second CIE b* color values (b1* and b2*); and
controlling optical thicknesses of the first and second refracting films so as to reduce the differential value (Δb*), thereby obscuring or hiding the pattern of the transparent conductive film, and improving color homogeneity.

13. The method of claim 12, wherein the optical thicknesses of the first and second refracting films are controlled such that the first and second CIE b* color values (b1* and b2*) are less than 1.15 and the differential value (Δb*) is less than 0.35.

14. The method of claim 13, further comprising a step of forming a modifying film on the substrate opposite to the first refracting film, wherein the first refracting film is controlled to have an optical thickness ranging from 11 nm to 16 nm, and the second refracting film is controlled to have an optical thickness ranging from 60 nm to 90 nm.

15. The method of claim 13, wherein the first refracting film is controlled to have an optical thickness ranging from 20 nm to 29 nm, and the second refracting film is controlled to have an optical thickness ranging from 60 nm to 90 nm.
